(19) United States
(12) Patent Application Publication
(10) Pub. No.: US 2012/0146214 A1
(43) Pub. Date: Jun. 14, 2012

(54) SEMICONDUCTOR DEVICE WITH VIAS AND FLIP-CHIP

(76) Inventor: Mehdi Frederik Soltan, Hong Kong (HK)

(21) Appl. No.: 12/964,737

(22) Filed: Dec. 9, 2010

(51) Int. Cl. H01L 23/52; H01L 21/44

(52) U.S. Cl. 257/737; 257/774; 257/741; 257/778; 438/667; 438/613; 257/E23.141; 257/E21.476

(57) ABSTRACT

Semiconductor devices comprising a flip-chip having passive circuits such as spiral inductors on the back side are disclosed.

Provision is made for connection with the spiral inductors using vias and/or bondwires.

Further aspects of the invention provide for methods of making such devices.

### RELATED APPLICATIONS

None.

### FIELD OF THE INVENTION

The present invention generally relates to electronic devices and circuits. The invention more particularly relates to implementation of circuit components, especially passive circuit components, such as inductors, that are used within and/or in conjunction with semiconductor devices that exploit flip-chip packages and related and allied materials and manufacturing techniques. Devices having similar or analogous topologies may fall within the general scope of the invention. The invention may be used in RF (Radio Frequency) and commonly microwave analog devices and find particular utility in such devices; however it may also find application in other types of electronic circuits and devices, such as mixed-signal devices.

### BACKGROUND OF THE INVENTION

Modernly, wireless communication products such as cellular radiotelephones are compact, lightweight, low power, incorporate sophisticated energy management and have a very competitive unit cost. Nonetheless, there is an unremitting drive to improvement in all those parameters, especially manufacturing costs, of which fab (active device fabrication) cost is a significant proportion.

In the above-referenced types of applications, although mixed signal devices are found in the art, commonly one or two semiconductor devices, or chips, are dedicated to the analog part of the circuit. Typically most of the analog circuit operates at RF, commonly in a microwave region. Flip-chip technologies have been preferred in some cases due to smaller path lengths. Alternative approaches, such as utilizing packages with lead frames and associated bond wires, are likely to be relatively more complex and/or expensive to manufacture and/or incorporate into products.

In previously developed devices discrete inductors have been used to provide inductive circuit elements which are used in resonant circuits, transmission lines and DC (direct current) chokes and so on. Bondwires (or bond wires) have been used as inductors; on-chip spiral inductors formed by metallization and/or etched into a semiconductor chips have also been used in conjunction with active circuits.

Q (Quality factor) is a particularly important property of an inductor since it directly affects the performance of RF circuits as is well known in the art. Q is an important parameter for inductors used in these types of applications regardless of the circuit design purpose of the inductor (component in a resonant circuit, as a transmission line or as a filter, especially loss pass filters and DC chokes).

Discrete component inductors increase the bill of materials part count and so are relatively expensive to use. Bondwire inductors have been proposed but are not in commonplace use at the time of writing (this may easily change) and it can be a challenge to provide a sufficient inductance to be optimal for some applications. Spiral inductors have also been used, but previously developed solutions have significant disadvantages, especially costs associated with semiconductor real estate devoted thereto and usually in displacement of die real estate that might otherwise be used for active circuits.

The many advantages of flip-chip technologies are well known, including factors such as reduced inductance in signal paths, shorter interconnect lengths, and also higher interconnect density, smaller package size, and possible reduction in die size. Prices and costs are becoming increasingly competitive in at least some configurations.

The invention provides a device and method to manufacture incorporated inductance features and the like used with flip-chip semiconductors having a better price/performance than has been possible with previous implementations. Thus, an advantage of the invention is that a better performing semiconductor based circuit that includes inductive component(s) may be built for a particular cost, or alternatively if a particular performance is specified then the overall cost may be lower than with products based on previously developed solutions.

### SUMMARY OF THE INVENTION

The present invention provides for an active semiconductor based device incorporating passive circuit, typically an inductive circuit.

According to an aspect of the present invention an embodiment of the invention may provide a flip-chip die with a backside passive circuit connected to active circuits on the front face by vias that pass through the die.

According to another aspect of the invention, a semiconductor die has a metal spiral inductor on a face and vias that connect to the opposite face which has both active circuits etched on it and off die connections such as solder or other metal bumps.

According to another aspect of the invention, bondwires are used instead of (or as well as) vias to provide interconnections.

According to an aspect of the present invention an embodiment of the invention an inventive device may be created by forming active circuits and metal pads on one face of a wafer, thinning the wafer, making holes through the wafer, metallizing the opposite face, making the holes into vias, removing metal from part of the metal layer to form a passive circuit and dicing the wafer.

### BRIEF DESCRIPTION OF THE DRAWINGS

The aforementioned and related advantages and features of the present invention will become better understood and appreciated upon review of the following detailed description of the invention, taken in conjunction with the following drawings, which are incorporated in and constitute a part of the specification, illustrate an embodiment of the invention and wherein like numerals represent like elements, and in which:

FIG. 1 shows a cross sectional view of an assembly according to an embodiment of the invention;

FIG. 2 shows a front-side plan view of a prior art flip-chip;

FIG. 3 shows a front-side plan view of a flip-chip die according to an embodiment of the invention;

FIG. 4 shows a cross-sectional view of the flip-chip die of FIG. 3.

FIG. 5 shows a back-side plan view of the flip-chip die of FIGS. 3 and 4.

FIG. 6 shows a cross-sectional view of a manufactured device according to a second embodiment of the invention.

FIG. 7 shows a flowchart for a method of creating a device according to an embodiment of the invention.

### DETAILED DESCRIPTION OF THE INVENTION

The numerous components shown in the drawings are presented to provide a person of ordinary skill in the art a thorough, enabling disclosure of the present invention. The description of well-known components is not included within this description so as not to obscure the disclosure or take away or otherwise reduce the novelty of the present invention and the main benefits provided thereby.

Embodiments of the disclosure presented herein provide for manufactures and methods of building them. In the following detailed description, references are made to the accompanying drawings that form a part hereof, and in which are shown by way of illustration specific embodiments or examples. Referring now to the drawings, in which like numerals represent like elements throughout the several figures, aspects of an exemplary operating environment and the implementations provided herein will be described.

Flip-chips are well-known in the semiconductor arts. Semiconductor wafers are processed, diced, and contacts or the like are provided for off-die electrical connection. In flip-chips active circuits and electrical contacts are formed on the same face of the die, this face is generally known as the front face of the die (or the front face of the wafer prior to dicing).

In typical embodiments of the invention a metal layer may be formed on the back face of the die for thermal, grounding, bias and/or noise suppression purposes. The back face of the die is commonly understood to be the face formed from the back face of the wafer from which the die is singulated. Wafers are thin sheets of semiconductor material having a front face and a back face. The front face is the face into which one or more active circuits is built and may be viewed as the obverse, with the back face being its corresponding reverse.

In the present context of chips with an operating region within the range 200 MHz to 100 GHz approximately there is less need for a back face grounding plane than with chips that are not flip-chips. This is at least in part due to the particularly short electrical path lengths inherent in the off-die connections of flip-chips. Techniques for creating metal layers on a surface of a semiconductor (such as by vapor deposition metallization) are well known.

In the present invention, one or more circuit elements or components is formed on the back face of the die, typically by removing metal from a metallized layer to create gaps therein. Such a circuit element is typically an inductor. In order that inductors so formed have a high Q number it is desirable that they have low ohmic resistance. This can be facilitated by ensuing that the metal layer is relatively thick and is composed of an excellent conductor of electricity. Gold works well in this regards, has excellent thermal properties and is a relatively easy material with which to work.

At typical operating frequencies, ohmic losses will typically dominate over other losses (such as eddy current losses) that can increase with conductor thickness but nonetheless remain relatively small at moderate frequencies, for example at 2 GHz. However at higher frequencies, for example at 60 GHz, eddy currents become significant and metallization thickness may have to be a design compromise.

Inductors thus formed in a back face metal layer can conveniently be of spiral form and may be connected to other circuit elements through bondwires or vias or both.

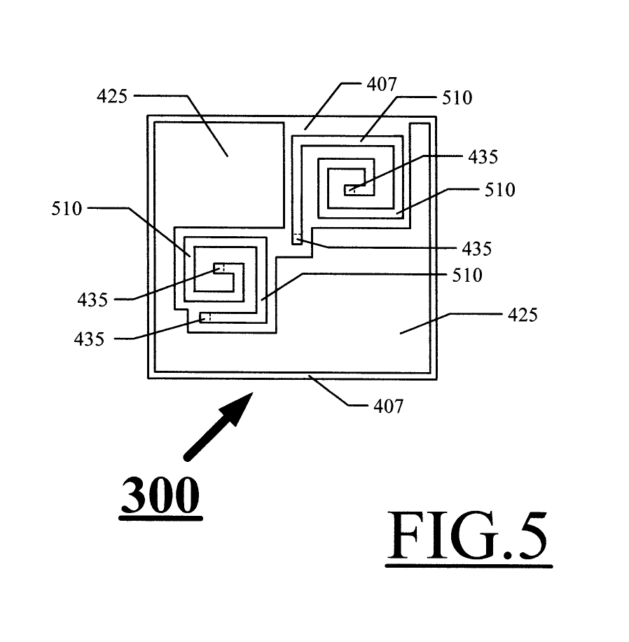

It should be understood that the term spiral is used herein consistent with the commonplace usage in the microelectronics art and should be so interpreted throughout. Inductors are rarely or never formed with a strictly spiral geometry (as the term spiral is understood in pure mathematics). In the semiconductor arts the term spiral is used more colloquially be mean what is more precisely known as a spirangle. Four-angle spirangles are easier to design, machine and fabricate than true spirals or indeed other types of spirangles due to the inherent rectilinear geometry; they are more typically deployed in so-called printed inductors (spirangles known as spirals in the art are shown in FIG. 5).

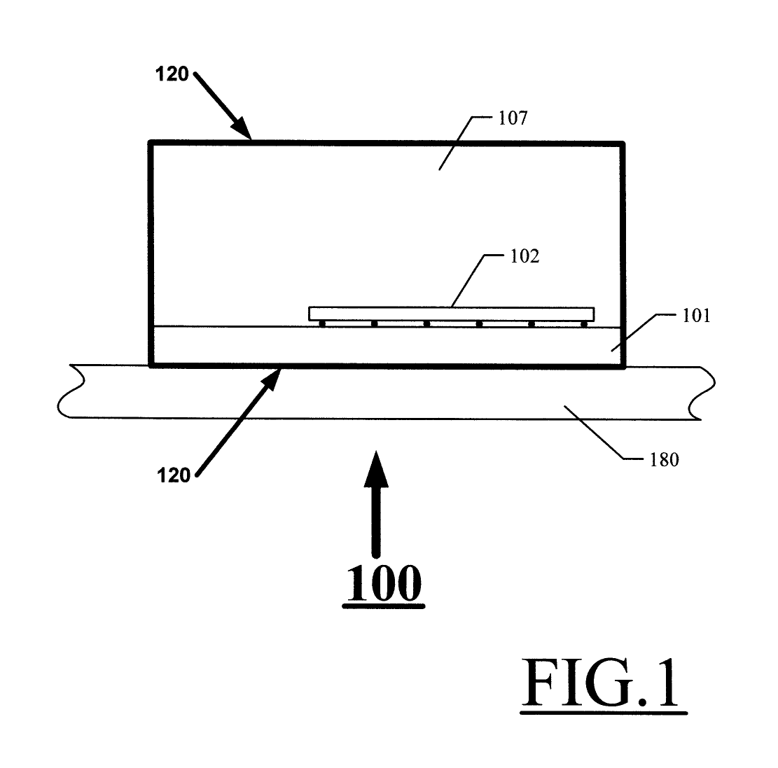

Exemplary embodiments of the present invention will now be described with reference to the figures. FIG. 1 shows a cross sectional view of an assembly 100 according to an embodiment of the invention. A manufactured device 120 may be incorporated as part of the assembly 100 by attachment to a structure 180 which may be a PCB (printed circuit board) or a PWA (printed wire assembly) according to an embodiment of the invention.

As shown, in this exemplary embodiment of the invention, manufactured device 120 is a package that comprises a package substrate 101, a flip-chip 102 and a package molding 107.

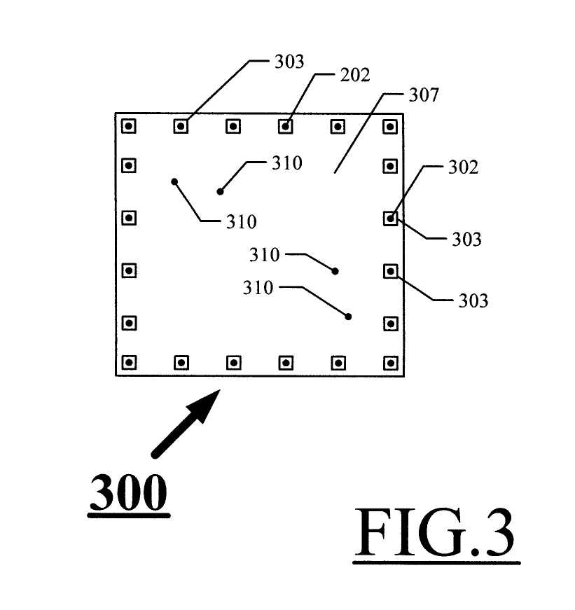

Still referring to FIG. 1, package substrate 101 may be a laminate PCB component. Flip-chip 102 may be as described below with reference to FIG. 3; it incorporates features that are novel in combination with aspects of the various exemplary embodiments of the invention. Package molding 107 may be a molded void-filling substance that is electrically non-conducting; the deployment of such things is well known in the art.

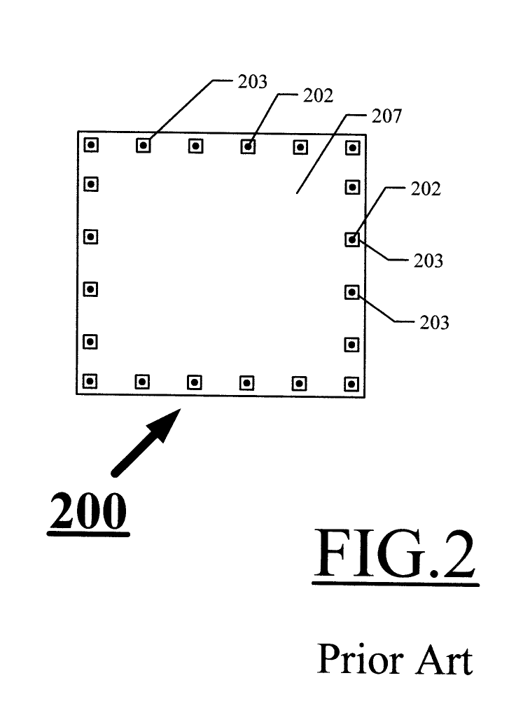

FIG. 2 shows a front-side plan view of a prior art flip-chip 200. A flip-chip 200 is typically a die cut from a semi-conductor wafer (not shown) as is well known in the art. In a typical flip-chip, much of the front face 207 of the die is faced and clad with active circuits (not shown) formed by Damascene deposition, etching and other methods ordinarily used in the semiconductor fabrication arts. Moreover, metal pads 203 provide electrical connection between some of the active circuits and solder bumps 202. Although metal pads 203 with solder bumps 202 are shown around the periphery that is only a typical configuration and is not a critical feature. It is also common to have such connections over the entire front face of the flip-chip. This prior art flip-chip 200 has no vias therein.

FIG. 3 shows a front-side plan view of a flip-chip die 300 cut according to an embodiment of the invention, from a semi-conductor wafer (not shown). As in prior art devices, much of the front face 307 of the die may be faced and clad with active circuits (not shown) formed by Damascene deposition, etching and other methods. Typically, metal pads 303 provide electrical connection between some of the active circuits and solder bumps 302 each of which is in contact with a respective metal pad 303.

Although metal pads 303 with associated solder bumps 302 are shown arranged around the periphery of the die 300 this is a possible, perhaps typical, arrangement but not a critical feature of the invention. Metal pads 303 with associated solder bumps 302 may be arranged otherwise, possibly in a grid array of with two ranks of pads encircling the periphery of the die, or otherwise covering the entire surface completely.

Still referring to FIG. 3, also present on the front face 307 of the die are the ends of vias 310 which penetrate through die 300 and serve to provide electrical (and/or thermal) connection between a conductor within an active circuit (not shown) formed on the front face 307 of the die and metallization on the back face of the die (not shown in FIG. 3). Vias may be formed in various ways such as those described infra.

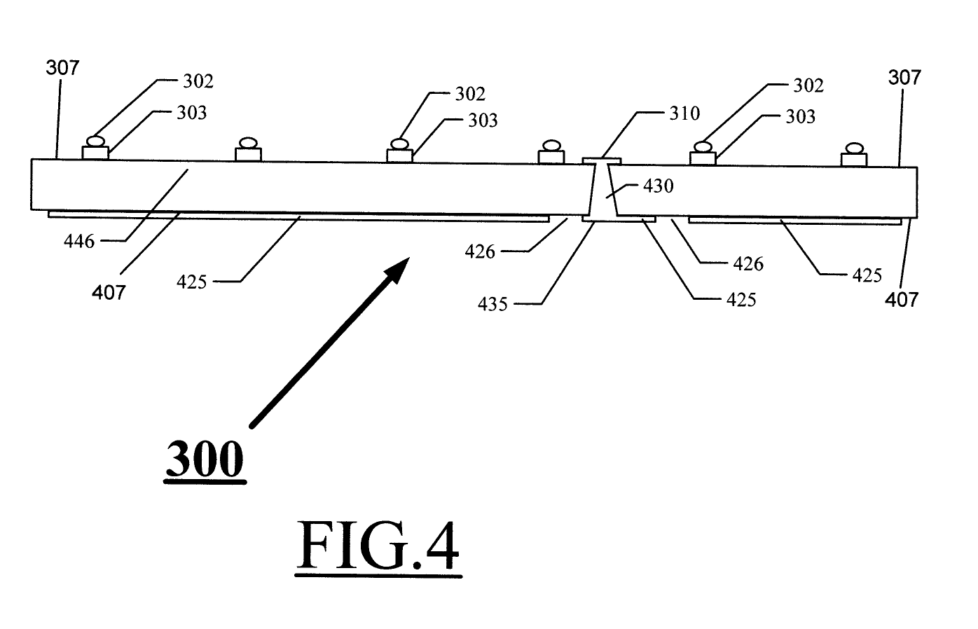

FIG. 4 shows a cross-sectional view of the flip-chip die 300 of FIG. 3 according to a first embodiment of the invention. The front face 307 of the die 300 will typically be formed with active circuit elements therein that are at least in part etched into the front part of semiconductor substrate 446. Passive circuits and other features may also be present in addition to the active circuits. Metal pads 303 with adjoining solder bumps 302 are also shown.

The back face 407 of the die 300 may be clad with a metal layer 425 into which gaps 426 are etched, milled or otherwise formed to create conducting traces within the metal layer 425 and also to form the back end(s) 435 of via(s). Circuits formed in and/or on the back face of a die are sometimes known as backside circuits.

For each via present, the front end 310 is electrically and thermally connected to the back end 435 by a metal conductor 430 which is typically pillar shaped or may be a slice of a cone or similar. The provision of vias to connect front face to back face of a flip-chip is not typical in the art of flip-chip fabrication and this is discussed further below.

FIG. 5 shows a back-side plan view of the flip-chip die 300 of FIGS. 3 and 4. The back face 407 of the flip-chip is the face opposite to the front face (307 of FIGS. 3 and 4, not shown in FIG. 5). The back face is substantially parallel to the front face (not shown). The die 300 is substantially flat and thin. Typically the back face is clad with metallization 425 whereas the front face incorporates active semiconductor circuits and other features. Any large areas of metallization 425 may serve thermal conducting and/or electrical shielding purposes (for example by being grounded) as is well known in the relevant arts. Due to the advantages inherent in flip-chip technology there may little need for a grounding plane as compared semiconductors based on the use of lead-frames.

Still referring to FIG. 5, four back ends 435 of vias are shown bonded and electrically connected to conducting traces 510 formed from selective removal of parts of back face metallization 425. In the exemplary embodiment of the invention depicted in FIG. 5, two spiral inductors each having two terminals (which are each at via ends 435) are formed with conducting traces 510.

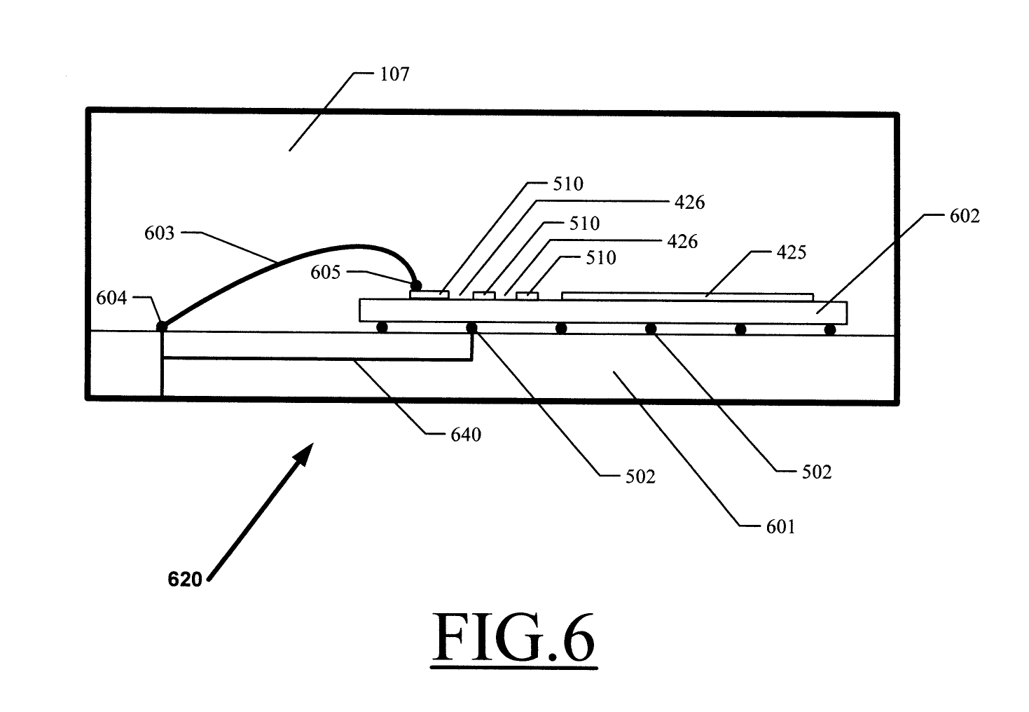

FIG. 6 shows a cross-sectional view of manufactured device 620 according to a second embodiment of the invention. Manufactured device 620 is a package that comprises a package substrate 601, a flip-chip semiconductor substrate 602 and a package molding 107.

Still referring to FIG. 6, package substrate 601 may be a laminate PCB similar to the device of FIG. 1. Package molding 107 may be a molded void-filling insulator. Bondwire 603 may be a conducting wire, typically a solid (non-stranded) drawn metal wire having a good or excellent specific conductivity. Bondwire 603 may be bonded at its two ends 604, 605 using conventional semiconductor chip bondwire technologies that are well known in the art.

Bondwire 603 may connect at an endpoint 605 to a spiral inductor 510 which is substantially the same as the spiral inductor formed described above in connection with FIG. 5. Spiral inductor 510 may be formed in a metallized layer 425 on the back face of semiconductor substrate 602 by forming gaps in the metallization layer 425 using any of various techniques such as etching gaps 426. As shown in FIG. 6, spiral inductor 510 may consist of a number of turns.

Inductor 510 may be electrically connected to active and/or passive circuits formed in the front face of semiconductor substrate 602 through bondwire 603, thence through buried conductors 640 formed in package substrate 601 and also through solder bumps 502 adjoining metal pads formed on the front face of the semiconductor substrate 602.

Buried conductors 640 may be formed in package substrate 601 by various methods, for example by well-known multi-layer printed circuit board techniques for embedding metal conductors and vias.

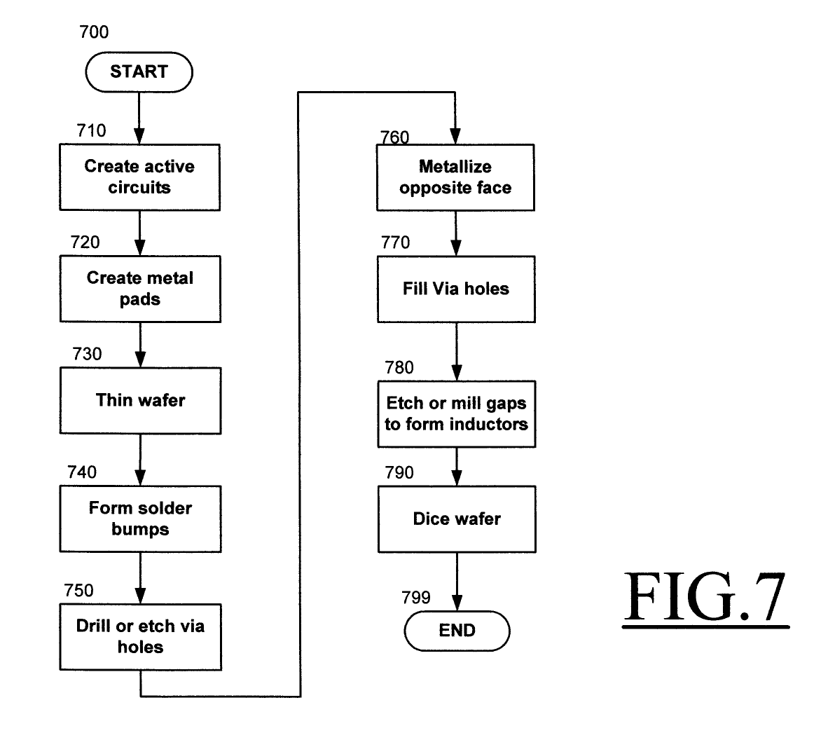

FIG. 7 shows a flowchart for a method of creating a flip-chip according to an embodiment of the invention. At 700 the method starts. At 710 active circuits are created in the front face of a semiconductor wafer. At 720 metal pads are also created in the front face of a semiconductor wafer.

At 730 the wafer is thinned to accommodate plating the vias. Thinning the wafer facilitates forming the vias. However, for reasons of mechanical integrity the holes are formed after the many steps of deposition and etching typically required to form active circuits.

At 740 solder bumps are formed on the metal pads. In an alternative embodiment of the invention the acts are steps 730 and 740 may be performed in the reverse sequence, the choice between embodiments being a matter of process convenience according to the type of fab facilities available and as a matter of operational efficiency.

At 750 holes for vias are drilled, etched or otherwise made between front and back faces of the wafer.

At 760 the back face of the wafer is metallized. At 770 the Vias are filled with conducting material such as gold.

At 780 gaps are etched, milled or otherwise created in the back face metallization in order to fashion spiral inductors in the metal on the back face of the wafer. At 790 the wafer is diced. At 799 the method ends.

In a still further embodiment of the invention a layer of passivation may be formed over the solder bumps and front chip face (not shown in FIG. 7). The passivation on the tips of solder bumps may be removed to expose metal for chip mounting. Adding passivation in this way can add needed mechanical strength and/or rigidity during Via processing and otherwise.

Some details of purely exemplary embodiments of the invention will now be given. These examples are by way of describing particular embodiments and the design features, especially numeric values, should be taken as successful examples rather than as critical or limiting features of the invention. The features are to be viewed as workable rather than as typical.

As to package substrates (for example 602 of FIG. 6), non-conducting board materials for RF (radio frequency) circuits are well-known in the art and may include types such as FR4, Rogers RT/Duroid, and/or Rogers R04003. Multiple grades and forms are available with disparate electrical properties and characteristics at various costs. Such materials can also be assembled in a variety of different ways potentially using multiple laminates, disparate materials and other features such as Damascene pattern conductors and plated through vias that are well known in the art. PCB conducting traces are typically made of copper but various finishes can be used by making use of materials such as Tin, Lead, Nickel, or Gold. Conducting pads (not shown in the drawings) may be present on the external face of the package substrate to provide external interconnects for a complete device).

Flip-chips may typically be fabricated from a Si, SiGe or complex III-V semiconductor material such as InGaP, GaAs/AlGaAs, InP, and GaN. They may comprise devices such as BJT/HBT (bipolar junction transistor/heterojunction bipolar transistor, HEMT (High electron mobility transistor) and/or FET (Field-effect transistor).

The exemplary device of FIGS. 3, 4 and 5 may comprise a GaAs based die. In a typical embodiment of the invention, solder bumps (302 of FIG. 4) may be formed from a solder alloy, but other metals such as gold or copper have been used in other embodiments. Conductive bumps are deposited on metal pads (303 of FIG. 4) on the front face which is at that time the top side of the semiconductor wafer during one of the later steps in wafer processing. After dicing, when the flip-chip die is ready to be mounted to a package substrate, the die is inverted (flipped over) so that the front face, becomes the lower surface. Conversely, flipping causes the backside of the flip-chip to become the upper surface. Conductive bumps 305 are formed onto metal pads 315 only on the front face of the flip-chip.

To allow for electrical connections between front side and back side, via holes are typically plated with gold. Vias can also improve heat dissipation performance and this effect may be utilized by design to good and/or necessary effect. The size of a via hole is determined responsive primarily to substrate thickness; for example a circular pattern having a 50- to 60-μm diameter may be used on a substrate thinned down from 20 to 30 mils thick to 4 to 8 mils thick.

A plated gold layer may be used to metallize the reverse face (also known as backside) of the die. Inductors formed in such metallization may achieve an adequate Q with approximately a 4 to 4.5 microns (or more) thickness of gold metal layer.

Flip-chip packaging technology has been used extensively used in the art. In order to mount the die to a substrate, conductive bumps on the front face may be aligned with matching pads of a package substrate. The conductive bump material may be flowed or re-flowed to complete an interconnection between each pad supporting a bump on the die to a corresponding pad on the package substrate.

As well as providing for conductive interconnect between chip and substrate, bumps may also provide thermal conduction paths from chip to package substrate or PCB. Conductive bumps may also act as spacers such as for preventing electrical shorts between the die and substrate circuit and/or to provide mechanical support to the flip-chip. There exist well known processes in the art for implementing flip-chip bumps, for example so-called solder bumping, Au (gold) stud, and Cu (copper) stud bumping. Solder bumping is typically achieved by placing UBM (under-bump metallization) over bond pads such as by sputtering, plating, or similar means. Copper bumping is used more modernly; it provides good reliability, wide temperature range stability, mechanical strength, high connection density, excellent manufacturability, and superior electrical and heat-dissipating performance.

Other topologies and/or devices could also be used to construct alternative embodiments of the invention. The embodiments described above are exemplary rather than limiting and the bounds of the invention should be determined from the claims. Although preferred embodiments of the present invention have been described in detail hereinabove, it should be clearly understood that many variations and/or modifications of the basic inventive concepts herein taught which may appear to those skilled in the present art will still fall within the spirit and scope of the present invention, as defined in the appended claims.

What is claimed is:

1. A device comprising:
a flip-chip die having
a front face having a plurality of electrical contacts thereon for off-die electrical connection,
a back face substantially parallel to the front face, the back face having a backside circuit formed thereon and
a plurality of vias that electrically connect an active circuit formed on the front face to the backside circuit.

2. The device of claim 1 wherein:
the plurality of electrical contacts are metal pads having metal bumps thereon.

3. The device of claim 1 wherein:
the back face has a metallization layer thereon and the backside circuit is formed in the metallization layer.

4. The device of claim 3 wherein:
the backside circuit is a spiral inductor.

5. The device of claim 4 wherein:
the metallization layer consists substantially of gold of more than about 4 microns (micrometers) thickness.

6. The device of claim 4 wherein:
the spiral inductor is a DC (direct current) power supply choke.

7. The device of claim 4 wherein:
the spiral inductor is comprised within a circuit having a resonance at an operating frequency of the device.

8. A device comprising:
a semiconductor die having a front face, a back face and a plurality of vias that electrical connect an active circuit formed in the front face to at least one inductor at the back face;
a metal layer adjoining the back face, the metal layer comprising the at least one inductor and
a plurality of electrical connections formed on the front face, the electrical connections for connecting to a circuit off the die,
wherein the front face is substantially parallel to the back face.

9. The device of claim 8 wherein:
each inductor is a spiral inductor.

10. The device of claim 8 wherein:
the metal layer consists substantially of gold of at least about 4.5 microns (micrometers) thickness.

11. The device of claim 8 wherein:
the electrical connections comprise metal pads in contact with metal bumps.

12. The device of claim 9 wherein:
the spiral inductor is a DC (direct current) power supply choke.

13. A device comprising:
a flip-chip having a front face and a back face;
a package substrate bonded to the front face of the flip-chip and
a first bondwire electrically connected to the package substrate and connected to an inductor formed on the back face of the flip-chip.

14. The device of claim 13 further comprising:
a second bondwire electrically connected to the inductor.

15. The device of claim 13 wherein:
the inductor is a spiral inductor formed in a metallization on the back face of the flip-chip.

16. The device of claim 14 wherein:
the inductor is a spiral inductor formed in a metallization layer on the back face of the flip-chip.

17. A device formed by:
creating a plurality of active circuits and a plurality of metal pads on a first face of a semiconductor wafer;
metallizing a second face of the semiconductor wafer to create a metal layer, the second face being substantially parallel to the first face;
creating at least one circuit element by removing metal from part of the metal layer and
creating an electrical connection between a circuit selected from the plurality of active circuits and the at least one circuit element.

18. The device of claim 17 wherein the electrical connection comprises a bondwire.

19. The device of claim 17 wherein the electrical connection comprises a via connecting a metal pad selected from the plurality of metal pads to the metal layer.

20. The device of claim 17 further formed by
depositing metal bumps on the metal pads.

21. A device formed by:
creating a plurality of active circuits and a plurality of metal pads on a first face of a semiconductor wafer to create a front face of the semiconductor wafer;
thinning the wafer on an opposite face of the semiconductor wafer to the front face of the semiconductor wafer;
opening at least one hole through the semiconductor wafer from the first face to the opposite face;
metallizing the opposite face of the semiconductor wafer to create a metal layer;
filling the at least one hole with a conducting material and
removing a part of the metal layer to form an inductor.

22. The device of claim 21 further formed by
depositing metal bumps on the metal pads prior to thinning the semiconductor wafer.

23. The device of claim 21 further formed by
depositing metal bumps on the metal pads after thinning the semiconductor wafer.

24. The device of claim 21 further formed by
dicing the semiconductor wafer to create a flip-chip die.

25. The device of claim 21 wherein
the inductor is substantially in a form of a rectilinear spirangle.

26. The device of claim 24 further formed by
bonding the flip-chip die to a substrate and
attaching a bondwire from the substrate to the metal layer.

27. The device of claim 22 further formed by
depositing a passivation layer over the metal bumps.

28. The device of claim 23 further formed by
depositing a passivation layer over the metal bumps.
